(19) United States
(12) Patent Application Publication
(10) Pub. No.: US 2025/0366324 A1
(43) Pub. Date: Nov. 27, 2025

(54) DISPLAY PANEL AND DISPLAY DEVICE

(71) Applicant: Wuhan China Star Optoelectronics Semiconductor Display Technology Co., Ltd., Wuhan, Hubei (CN)

(72) Inventor: Lixia YANG, Wuhan, Hubei (CN)

(73) Assignee: Wuhan China Star Optoelectronics Semiconductor Display Technology Co., Ltd., Wuhan, Hubei (CN)

(21) Appl. No.: 18/851,779

(22) PCT Filed: Jun. 29, 2023
(86) PCT No.: PCT/CN2023/104265

§ 371 Date: Sep. 27, 2024

(30) Foreign Application Priority Data
Nov. 22, 2022 (CN) 202211468171.8

(51) Int. Cl. H10K 59/131; H10K 59/12; H10K 59/122; H10K 59/80

(52) U.S. Cl. CPC H10K 59/131; H10K 59/1201; H10K 59/122; H10K 59/873

(57) ABSTRACT

A display panel and a display device are provided. A boundary of a light-emitting functional layer in a non-display area is located between a second trace sub-area and a display area. Accordingly, in a narrow bezel design, the light-emitting functional layer is prevented from covering a conductive trace in the non-display area, thereby avoiding abnormal electrical connections between the conductive trace in the non-display area and a second conductive layer.

### FIELD OF DISCLOSURE

The present application relates to a field of display technology, and more particularly, to a display panel and a display device.

### DESCRIPTION OF RELATED ART

Organic light-emitting diode (OLED) devices, also known as organic electroluminescent displays or organic light-emitting semiconductor, have advantages such as low voltage requirement, high power-saving efficiency, fast response, light weight, thin thickness, simple structure, low cost, wide viewing angle, almost infinite contrast ratio, lower power consumption, and extremely high response speed. The OLED Technology has become one of the most important display technologies today.

In order to enhance the user's experience, the bezel of the display panel is gradually decreasing. To meet customer needs, display panel manufacturers are also developing narrow bezel technologies.

### SUMMARY OF INVENTION

Currently, to prevent the light-emitting functional layer from affecting the electrical connection performance of the conductive unit and the cathode, the light-emitting functional layer reserves alignment accuracy during bezel design. The extent of the light-emitting functional layer's distribution in the bezel area is related to the manufacturer's production capabilities. When designing a narrow bezel, on the one hand, the distribution range of the light-emitting functional layer can be compressed. However, this may lead to the light-emitting functional layer being too thin within some openings at the edge of the pixel definition layer, resulting in abnormal light emission from the display panel. Moreover, existing processes may not be able to compress the distribution range of the light-emitting functional layer. On the other hand, if the distribution range of the light-emitting functional layer is not compressed, it can cover the conductive units in the non-display area, affecting the connection between the conductive unit and the cathode in the non-display area, leading to abnormal scrapping of the display panel.

An objective of the present invention is to provide a display panel and a display device that can address the issues existing in conventional techniques, such as abnormal light emission from the display panel and difficulties in the manufacturing process when compressing the distribution range of the light-emitting functional layer, as well as abnormal scrapping of the display panel when the distribution range of the light-emitting functional layer is not compressed.

In order to address the above issues, the present invention provides a display panel, including: a display area and a non-display area disposed on at least one side of the display area, wherein the non-display area includes a first trace sub-area, a gate driver sub-area, and a second trace sub-area, arranged sequentially towards the display area; wherein the display panel further includes: a substrate; a driver circuit layer, disposed on one side of the substrate, wherein the driver circuit layer includes a plurality of pixel driver circuits disposed in the display area, a first trace disposed in the first trace sub-area, a gate driver circuit disposed in the gate driver sub-area, and a second trace disposed in the second trace sub-area, wherein the gate driver circuit is electrically connected to a corresponding one of the pixel driver circuits, and the second trace is electrically connected to a corresponding one of the pixel driver circuits; a planarization layer, disposed on one side of the driver circuit layer away from the substrate; a first conductive layer, disposed on one side of the planarization layer away from the substrate, wherein the first conductive layer includes a conductive trace disposed in the non-display area and a plurality of first electrodes disposed in the display area, wherein each of the first electrodes is electrically connected to a corresponding one of the pixel driver circuits, and the conductive trace is electrically connected to the first trace; a pixel definition layer, disposed on one side of the first conductive layer away from the substrate, wherein the pixel definition layer includes a plurality of pixel openings corresponding to the first electrodes; a light-emitting functional layer, disposed on one side of the pixel definition layer away from the substrate, wherein the light-emitting functional layer covers the display area and extends to the non-display area, and a boundary of the light-emitting functional layer in the non-display area is located between the second trace sub-area and the display area; and a second conductive layer, disposed on one side of the light-emitting functional layer away from the substrate, wherein the second conductive layer covers the display area and extends to the non-display area, and is electrically connected to the conductive trace.

Furthermore, the boundary of the light-emitting functional layer in the non-display area is between the second trace and the display area.

Furthermore, the conductive trace is spaced apart from the light-emitting functional layer, and the second conductive layer is also in direct contact with at least a portion of an upper surface of the planarization layer located between the conductive trace and the light-emitting functional layer.

Furthermore, roughness of at least a portion of a surface on one side of the conductive trace away from the substrate is greater than roughness of a surface on one side of the first electrode away from the substrate.

Furthermore, a thickness of the planarization layer located between the conductive trace and the pixel definition layer is less than a thickness of the planarization layer in the display area.

Furthermore, the pixel definition layer includes a step structure on one side close to the non-display area, and the boundary of the light-emitting functional layer in the non-display area is between the step structure and the display area.

Furthermore, the second conductive layer covers the step structure.

Furthermore, the display panel further includes: a first bank, disposed on one side of the planarization layer away from the substrate, and at least a portion of the conductive trace is disposed between the first bank and the planarization layer; and a second bank, disposed on one side of the planarization layer away from the substrate, and located on one side of the first bank away from the display area, wherein at least a portion of the conductive trace is disposed between the first bank and the planarization layer.

Furthermore, the display panel further includes: an encapsulation layer, disposed on one side of the second conductive layer away from the substrate, wherein the encapsulation layer includes a first inorganic encapsulation sub-layer, an organic encapsulation sub-layer, and a second inorganic encapsulation sub-layer sequentially stacked, wherein the first inorganic encapsulation sub-layer is in direct contact with an upper surface of the conductive trace between the first bank and the second bank.

In order to address the above issues, the present invention further provides a display device. The display device includes the display panel of the present application.

### BENEFICIAL EFFECTS

In the narrow bezel design of the display panel according to the present invention, the distribution range of the light-emitting functional layer is not compressed. Instead, the light-emitting functional layer on the conductive trace in the non-display area, the planarization layer in the non-display area, and part of the pixel definition layer in the non-display area are removed through laser etching. This ensures that the boundary of the light-emitting functional layer in the non-display area is located between the second trace sub-area and the display area. Consequently, in the narrow bezel design, the light-emitting functional layer is prevented from covering the conductive trace in the non-display area, thus preventing any abnormal electrical connections between the conductive trace in the non-display area and the second conductive layer.

### BRIEF DESCRIPTION OF DRAWINGS

To further illustrate the technical solutions in the embodiments of the present application, the drawings used in the description of the embodiments are briefly introduced below. Obviously, the drawings described below are only some embodiments of the present application. For those skilled in the art, other drawings can be obtained based on these drawings without inventive effort.

FIG. 1 is a plan view of a display panel according to a first embodiment of the present invention.

FIG. 2 is a cross-sectional view taken along line A-A in FIG. 1.

FIG. 3 is a schematic structural view showing a light-emitting unit and a light-emitting functional layer on a pixel electrode according to the first embodiment.

FIG. 4 is a process flow diagram illustrating manufacturing steps for the display panel according to the first embodiment of the present invention.

FIG. 5 is a schematic view of laser etching the light-emitting functional layer on a conductive unit according to the first embodiment of the present invention.

FIG. 6 is a schematic structural view of the display panel according to the second embodiment of the present invention.

FIG. 7 is a schematic view of laser etching the light-emitting functional layer on the conductive unit according to the second embodiment of the present invention.

### DETAILED DESCRIPTION OF EMBODIMENTS

The example embodiments of the present invention are described in detail below in conjunction with the accompanying drawings, so as to provide those skilled in the art with a complete introduction to the technical content of the present invention, to exemplify that the present invention can be implemented, and to make the disclosed technical content of the present invention clearer, so that those skilled in the art can more easily understand how to implement the present invention. However, the present invention can be embodied in many different forms of embodiments, and the scope of protection of the present invention is not limited to the embodiments mentioned in the text. The description of the embodiments below is not intended to limit the scope of the present invention.

The directional terms mentioned in the present invention, such as “upper,” “lower,” “front,” “rear,” “left,” “right,” “inner,” “outer,” “side,” etc., are only the directions in the drawings. The directional terms used in this disclosure are used to explain and illustrate the present invention, and are not intended to limit the scope of protection of the present invention.

In the drawings, components with the same structure are represented by the same reference numerals, and components with similar structures or functions in various places are represented by similar reference numerals. In addition, for the convenience of understanding and description, the size and thickness of each component shown in the drawings are not to scale, and the present invention does not limit the size and thickness of each component.

### First Embodiment

This embodiment provides a display device. The display device can include a mobile phone, computer, MP3, MP4, tablet computer, television, digital camera, or the like. The display device includes a display panel 100. The display panel 100 includes a display area 101 and a non-display area 102 arranged on at least one side of the display area 101.

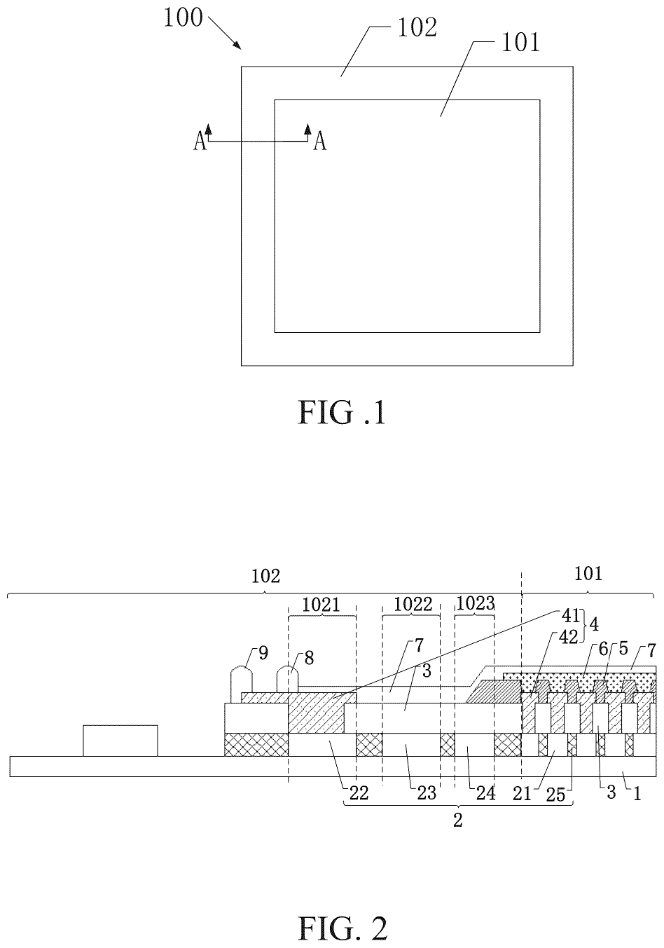

As shown in FIG. 1, in the present embodiment, the display panel 100 includes the display area 101 and the non-display area 102 surrounding the display area 101.

As shown in FIG. 2, the non-display area 102 includes: a first trace sub-area 1021, a gate driver sub-area 1022, and a second trace sub-area 1023, arranged sequentially towards the display area 101.

As shown in FIG. 2, the display panel 100 includes: a substrate 1, a driver circuit layer 2, a planarization layer 3, a first conductive layer 4, a pixel definition layer 5, a light-emitting functional layer 6, and a second conductive layer 7.

The material of the substrate 1 may include glass, polyimide, polycarbonate, polyethylene terephthalate, polyethylene naphthalate, or the like. In this embodiment, the material of the substrate 1 is polyimide, so that the substrate 1 has better impact resistance and can effectively protect the display panel 100.

The driver circuit layer 2 is disposed on one side of the substrate 1. The driver circuit layer 2 includes: a pixel driver circuit 21, a first trace 22, a gate driver circuit 23, a second trace 24, and an insulating layer 25.

The pixel driver circuit 21 is disposed on one side of the substrate 1 in the display area 101. Multiple pixel driver circuits 21 are disposed at intervals on the substrate 1 in the display area 101. The pixel driver circuit 21 includes film layer structures such as an active layer (not illustrated), a gate (not illustrated), a source/drain (not illustrated), and a gate insulating layer (not illustrated).

The first trace 22 is disposed on one side of the substrate 1 in the first trace sub-area 1021. In this embodiment, the first trace 22 is a low-voltage power supply line.

The gate driver circuit 23 is disposed on one side of the substrate 1 in the gate driver sub-area 1022. The gate driver circuit 23 is electrically connected to the corresponding pixel driver circuit 21.

The second trace 24 is disposed on one side of the substrate 1 in the second trace sub-area 1023. In this embodiment, the second trace 24 is a reset signal line. The second trace 24 is electrically connected to the corresponding pixel driver circuit 21.

The insulating layer 25 is disposed on the substrate 1 between two adjacent pixel driver circuits 21, and also between the first trace 22 and the gate driver circuit 23, between the gate driver circuit 23 and the second trace 24, and between the second trace 24 and the pixel driver circuit 21 on the substrate 1. The insulating layer 25 can be formed by extending the gate insulating layer or other insulating film layers of the pixel driver circuit 21.

The planarization layer 3 is disposed on one side of the driver circuit layer 2 away from the substrate 1. The material of the planarization layer 3 can be SiOx, SiNx, SiNOx, a composite structure of SiNx and SiOx, etc. The planarization layer 3 mainly provides a flat surface for the preparation of film layers on one side away from the substrate 1.

The first conductive layer 4 is disposed on one side of the planarization layer 3 away from the substrate 1. The first conductive layer 4 includes: a conductive trace 41 disposed in the non-display area 102 and a plurality of first electrodes 42 disposed in the display area 101. The first electrode 42 is electrically connected to the corresponding pixel driver circuit 21, and the conductive trace 41 is electrically connected to the first trace 22. Specifically, each first electrode 42 passes through the planarization layer 3 and is electrically connected to the drain of the corresponding pixel driver circuit 21. In this embodiment, the material of the first electrode 42 is the same as the material of the conductive trace 41, so that the first electrode 42 and the conductive trace 41 can be formed in the same process. In other embodiments, the material of the first electrode 42 may be different from the material of the conductive trace 41.

The pixel definition layer 5 is disposed on one side of the first conductive layer 4 away from the substrate 1, and the pixel definition layer 5 includes a plurality of pixel openings corresponding to the first electrodes 42. It is worth noting that, in this embodiment, a boundary between the display area 101 and the non-display area 102 is a boundary of a projection on the substrate 1 of the outermost pixel opening of the pixel definition layer 5.

The light-emitting functional layer 6 is disposed on one side of the pixel definition layer 5 away from the substrate 1. The light-emitting functional layer 6 covers the display area 101 and extends to the non-display area 102.

A boundary of the light-emitting functional layer 6 in the non-display area 102 is between the second trace sub-area 1023 and the display area 101. Specifically, the boundary of the light-emitting functional layer 6 in the non-display area 102 is between the second trace 24 and the display area 101. Therefore, when the display panel 100 is designed with a narrow bezel, a distribution range of the light-emitting functional layer 6 is not compressed. Instead, by using laser etching to remove the light-emitting functional layer 6 that covers the conductive trace 41 in the non-display area 102, the planarization layer 3 in the non-display area 102, and part of the pixel definition layer 5 in the non-display area 102, the boundary of the light-emitting functional layer 6 in the non-display area 102 is positioned between the second trace 24 and the display area 101. This prevents the light-emitting functional layer 6 from covering the conductive trace 41 in the non-display area 102 during narrow bezel design, thus avoiding abnormal electrical connections between the conductive trace 41 in the non-display area 102 and the second conductive layer 7.

The second conductive layer 7 is disposed on one side of the light-emitting functional layer 6 away from the substrate 1. The second conductive layer 7 covers the display area 101 and extends to the non-display area 102, and is electrically connected to the conductive trace 41.

The conductive trace 41 is spaced apart from the light-emitting functional layer 6, and the second conductive layer 7 is also in direct contact with at least a portion of an upper surface of the planarization layer 3 located between the conductive trace 41 and the light-emitting functional layer 6.

To achieve a narrow bezel design, the structure of the non-display area 102 needs to be compressed. In this embodiment, the display panel 100 further includes a first bank 8 and a second bank 9.

The first bank 8 is disposed on one side of the planarization layer 3 away from the substrate 1, and at least a portion of the conductive trace 41 is disposed between the first bank 8 and the planarization layer 3.

The second bank 9 is disposed on one side of the planarization layer 3 away from the substrate 1, and is located on one side of the first bank 8 away from the display area 101, wherein at least a portion of the conductive trace 41 is disposed between the first bank 8 and the planarization layer 3.

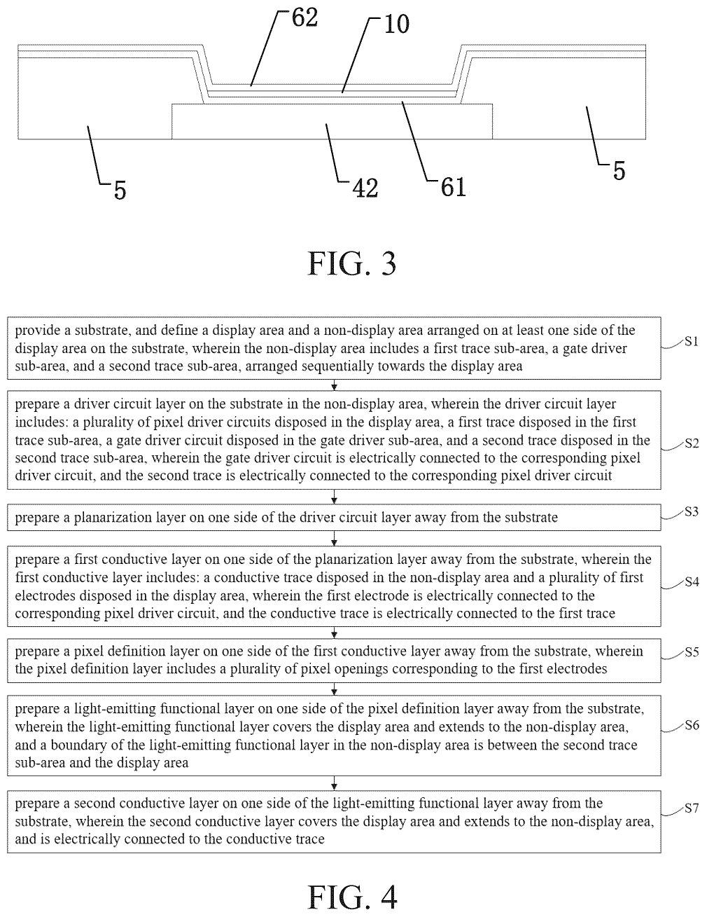

As shown in FIG. 3, the display panel 100 further includes a plurality of light-emitting units 10. The light-emitting units 10 are disposed in one-to-one correspondence in the pixel openings of the pixel definition layer 5.

As shown in FIG. 3, the light-emitting functional layer 6 includes a first light-emitting functional layer 61 and a second light-emitting functional layer 62.

The first light-emitting functional layer 61 is disposed between the light-emitting unit 10 and the first electrode 42, and extends to cover a surface of the pixel definition layer 5 on one side away from the substrate 1. Specifically, the first light-emitting functional layer 61 includes film layer structures such as a hole injection layer, a hole transport layer, and an electron blocking layer.

The second light-emitting functional layer 62 is disposed on one side of the light-emitting unit 10 away from the substrate 1, and extends to cover the first light-emitting functional layer 61. Specifically, the second light-emitting functional layer 62 includes film layer structures such as an electron transport layer, an electron injection layer, and a hole blocking layer.

The display panel 100 further includes an encapsulation layer (not illustrated) disposed on one side of the second conductive layer 7 away from the substrate 1. The encapsulation layer includes a first inorganic encapsulation sub-layer, an organic encapsulation sub-layer, and a second inorganic encapsulation sub-layer sequentially stacked. The first inorganic encapsulation sub-layer is in direct contact with an upper surface of the conductive trace 41 between the first bank 8 and the second bank 9.

As shown in FIG. 4, the present embodiment also provides a manufacturing method for the display panel 100 of the present embodiment, comprising the following steps. Step S1: Provide a substrate 1, and define a display area 101 and a non-display area 102 arranged on at least one side of the display area 101 on the substrate 1. The non-display area 102 includes: a first trace sub-area 1021, a gate driver sub-area 1022, and a second trace sub-area 1023, arranged sequentially towards the display area 101. Step S2: Prepare a driver circuit layer 2 on the substrate 1 in the non-display area 102. The driver circuit layer 2 includes: a plurality of pixel driver circuits 21 disposed in the display area 101, a first trace 22 disposed in the first trace sub-area 1021, a gate driver circuit 23 disposed in the gate driver sub-area 1022, and a second trace 24 disposed in the second trace sub-area 1023. The gate driver circuit 23 is electrically connected to the corresponding pixel driver circuit 21, and the second trace 24 is electrically connected to the corresponding pixel driver circuit 21. Step S3: Prepare a planarization layer 3 on one side of the driver circuit layer 2 away from the substrate 1. Step S4: Prepare a first conductive layer 4 on one side of the planarization layer 3 away from the substrate 1. The first conductive layer 4 includes: a conductive trace 41 disposed in the non-display area 102 and a plurality of first electrodes 42 disposed in the display area 101. The first electrode 42 is electrically connected to the corresponding pixel driver circuit 21, and the conductive trace 41 is electrically connected to the first trace 22. Step S5: Prepare a pixel definition layer 5 on one side of the first conductive layer 4 away from the substrate 1. The pixel definition layer 5 includes a plurality of pixel openings corresponding to the first electrodes 42. Step S6: Prepare a light-emitting functional layer 6 on one side of the pixel definition layer 5 away from the substrate 1. The light-emitting functional layer 6 covers the display area 101 and extends to the non-display area 102. A boundary of the light-emitting functional layer 6 in the non-display area 102 is between the second trace sub-area 1023 and the display area 101. Step S7: Prepare a second conductive layer 7 on one side of the light-emitting functional layer 6 away from the substrate 1. The second conductive layer 7 covers the display area 101 and extends to the non-display area 102, and is electrically connected to the conductive trace 41.

In this embodiment, the conductive trace 41 and the first electrodes 42 are formed in the same process. In other embodiments, the conductive trace 41 and the first electrodes 42 can also be prepared separately.

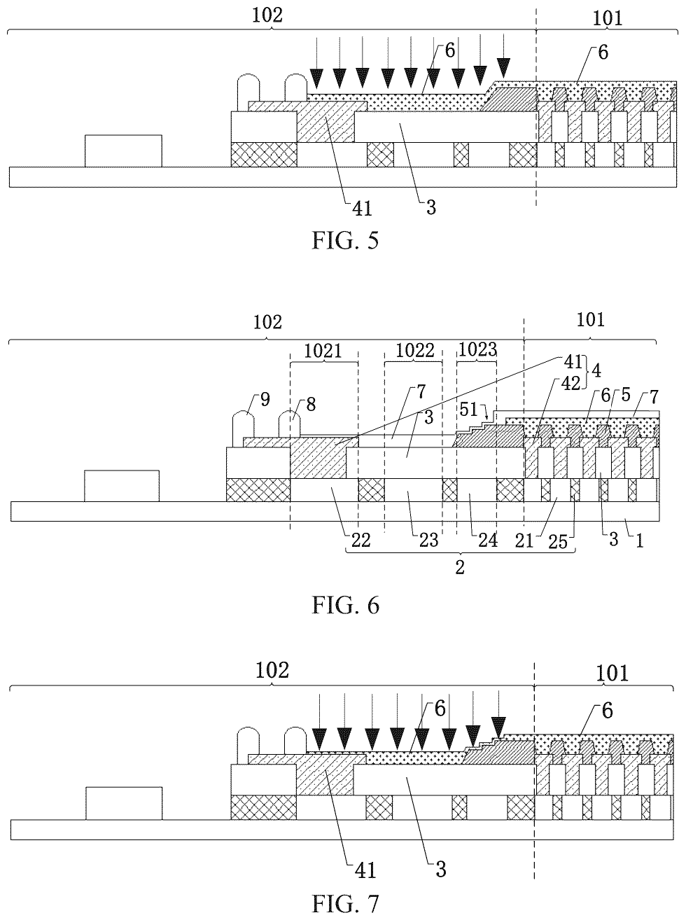

As shown in FIG. 5, in step S6, during the design of narrow bezels, the light-emitting functional layer 6 would normally cover the planarization layer 3 and the conductive trace 41 in the non-display area 102 if the distribution range of the light-emitting functional layer 6 were not compressed. However, by using laser etching to remove the light-emitting functional layer 6 that covers the conductive trace 41 in the non-display area 102, the planarization layer 3 in the non-display area 102, and part of the pixel definition layer 5 in the non-display area 102, the boundary of the light-emitting functional layer 6 in the non-display area 102 is positioned between the second trace 24 and the display area 101. This prevents the light-emitting functional layer 6 from covering the conductive trace 41 in the non-display area 102 during narrow bezel design, thus avoiding abnormal electrical connections between the conductive trace 41 in the non-display area 102 and the second conductive layer 7.

When laser etching is used to remove the light-emitting functional layer 6, due to the current precision limitations of the laser etching process, at least a portion of a surface on one side of the conductive trace 41 away from the substrate 1 is rough. The roughness of at least a portion of the surface on the side of the conductive trace 41 away from the substrate 1 is greater than the roughness of a surface on the side of the first electrode 42 away from the substrate 1.

When laser etching is used to remove the light-emitting functional layer 6, due to the current precision limitations of the laser etching process, a thickness of the planarization layer 3 located between the conductive trace 41 and the pixel definition layer 5 is less than a thickness of the planarization layer 3 in the display area 101.

### Second Embodiment

As shown in FIG. 6, this embodiment includes most of the technical features of the first embodiment. The difference between this embodiment and the first embodiment is that: in this embodiment, the pixel definition layer 5 in the non-display area includes at least one step structure 51 on one side closer to the non-display area 102. The boundary of the light-emitting functional layer 6 in the non-display area 102 is between the step structure 51 and the display area 102. The second conductive layer 7 covers the step structure 51. A shape of the step structure 51 includes at least one of a right angle and a rounded corner. In this embodiment, the shape of the step structure 51 is a right angle. Specifically, in this embodiment, at least one step structure 51 is formed on one side of the pixel definition layer 5 in the non-display area closer to the non-display area 102 before laser etching is used to remove the light-emitting functional layer 6. In other embodiments, at least one step structure 51 can be formed on one side of the pixel definition layer 5 in the non-display area 102 closer to the non-display area 102 during the process of laser etching to remove the light-emitting functional layer 6.

As shown in FIG. 7, during the design of narrow bezels, the light-emitting functional layer 6 would normally cover the planarization layer 3 and the conductive trace 41 in the non-display area 102 if the distribution range of the light-emitting functional layer 6 were not compressed. However, this design utilizes laser etching to remove the light-emitting functional layer 6 on the conductive trace 41 in the non-display area 102, the planarization layer 3 in the non-display area 102, and part of the pixel definition layer 5 in the non-display area 102. This ensures that the boundary of the light-emitting functional layer 6 in the non-display area 102 is between the second trace 24 and the display area 101. Consequently, in narrow bezel design, the light-emitting functional layer 6 is prevented from covering the conductive trace 41 in the non-display area 102, thus preventing any abnormal electrical connections between the conductive trace 41 in the non-display area 102 and the second conductive layer 7.

The foregoing has provided a detailed introduction to a display panel and a display device according to the present application. In this disclosure, specific examples have been used to illustrate the principles and implementation methods of the present application. The description of the above embodiments is only intended to help understand the methods and core ideas of the present application. At the same time, for those skilled in the art, based on the ideas of the present application, there will be changes in the specific implementation methods and application scope. In summary, the content of this specification should not be construed as limiting the present application.

What is claimed is:

1. A display panel, comprising:
a display area; and
a non-display area disposed on at least one side of the display area, wherein the non-display area comprises a first trace sub-area, a gate driver sub-area, and a second trace sub-area, arranged sequentially towards the display area;
wherein the display panel further comprises:
a substrate;
a driver circuit layer, disposed on one side of the substrate, wherein the driver circuit layer comprises a plurality of pixel driver circuits disposed in the display area, a first trace disposed in the first trace sub-area, a gate driver circuit disposed in the gate driver sub-area, and a second trace disposed in the second trace sub-area, wherein the gate driver circuit is electrically connected to a corresponding one of the pixel driver circuits, and the second trace is electrically connected to a corresponding one of the pixel driver circuits;
a planarization layer, disposed on one side of the driver circuit layer away from the substrate;
a first conductive layer, disposed on one side of the planarization layer away from the substrate, wherein the first conductive layer comprises a conductive trace disposed in the non-display area and a plurality of first electrodes disposed in the display area, wherein each of the first electrodes is electrically connected to a corresponding one of the pixel driver circuits, and the conductive trace is electrically connected to the first trace;
a pixel definition layer, disposed on one side of the first conductive layer away from the substrate, wherein the pixel definition layer comprises a plurality of pixel openings corresponding to the first electrodes;
a light-emitting functional layer, disposed on one side of the pixel definition layer away from the substrate, wherein the light-emitting functional layer covers the display area and extends to the non-display area, and a boundary of the light-emitting functional layer in the non-display area is located between the second trace sub-area and the display area; and
a second conductive layer, disposed on one side of the light-emitting functional layer away from the substrate, wherein the second conductive layer covers the display area and extends to the non-display area, and is electrically connected to the conductive trace.

2. The display panel according to claim 1, wherein the boundary of the light-emitting functional layer in the non-display area is between the second trace and the display area.

3. The display panel according to claim 2, wherein the conductive trace is spaced apart from the light-emitting functional layer, and the second conductive layer is also in direct contact with at least a portion of an upper surface of the planarization layer located between the conductive trace and the light-emitting functional layer.

4. The display panel according to claim 3, wherein roughness of at least a portion of a surface on one side of the conductive trace away from the substrate is greater than roughness of a surface on one side of the first electrode away from the substrate.

5. The display panel according to claim 3, wherein a thickness of the planarization layer located between the conductive trace and the pixel definition layer is less than a thickness of the planarization layer in the display area.

6. The display panel according to claim 2, wherein the pixel definition layer comprises a step structure on one side close to the non-display area, and the boundary of the light-emitting functional layer in the non-display area is between the step structure and the display area.

7. The display panel according to claim 6, wherein the second conductive layer covers the step structure.

8. The display panel according to claim 1, further comprising:
a first bank, disposed on one side of the planarization layer away from the substrate, and at least a portion of the conductive trace is disposed between the first bank and the planarization layer; and
a second bank, disposed on one side of the planarization layer away from the substrate, and located on one side of the first bank away from the display area, wherein at least a portion of the conductive trace is disposed between the first bank and the planarization layer.

9. The display panel according to claim 8, further comprising:
an encapsulation layer, disposed on one side of the second conductive layer away from the substrate, wherein the encapsulation layer comprises a first inorganic encapsulation sub-layer, an organic encapsulation sub-layer, and a second inorganic encapsulation sub-layer sequentially stacked.

10. The display panel according to claim 9, wherein the first inorganic encapsulation sub-layer is in direct contact with an upper surface of the conductive trace between the first bank and the second bank.

11. A display device, comprising a display panel, wherein the display panel comprises: a display area; and a non-display area disposed on at least one side of the display area, wherein the non-display area comprises a first trace sub-area, a gate driver sub-area, and a second trace sub-area, arranged sequentially towards the display area;
wherein the display panel further comprises:
a substrate;
a driver circuit layer, disposed on one side of the substrate, wherein the driver circuit layer comprises a plurality of pixel driver circuits disposed in the display area, a first trace disposed in the first trace sub-area, a gate driver circuit disposed in the gate driver sub-area, and a second trace disposed in the second trace sub-area, wherein the gate driver circuit is electrically connected to a corresponding one of the pixel driver circuits, and the second trace is electrically connected to a corresponding one of the pixel driver circuits;
a planarization layer, disposed on one side of the driver circuit layer away from the substrate;
a first conductive layer, disposed on one side of the planarization layer away from the substrate, wherein the first conductive layer comprises a conductive trace disposed in the non-display area and a plurality of first electrodes disposed in the display area, wherein each of the first electrodes is electrically connected to a corresponding one of the pixel driver circuits, and the conductive trace is electrically connected to the first trace;
a pixel definition layer, disposed on one side of the first conductive layer away from the substrate, wherein the pixel definition layer comprises a plurality of pixel openings corresponding to the first electrodes;
a light-emitting functional layer, disposed on one side of the pixel definition layer away from the substrate, wherein the light-emitting functional layer covers the display area and extends to the non-display area, and a boundary of the light-emitting functional layer in the non-display area is located between the second trace sub-area and the display area; and
a second conductive layer, disposed on one side of the light-emitting functional layer away from the substrate, wherein the second conductive layer covers the display area and extends to the non-display area, and is electrically connected to the conductive trace.

12. The display device according to claim 11, wherein the boundary of the light-emitting functional layer in the non-display area is between the second trace and the display area.

13. The display device according to claim 12, wherein the conductive trace is spaced apart from the light-emitting functional layer, and the second conductive layer is also in direct contact with at least a portion of an upper surface of the planarization layer located between the conductive trace and the light-emitting functional layer.

14. The display device according to claim 13, wherein roughness of at least a portion of a surface on one side of the conductive trace away from the substrate is greater than roughness of a surface on one side of the first electrode away from the substrate.

15. The display device according to claim 13, wherein a thickness of the planarization layer located between the conductive trace and the pixel definition layer is less than a thickness of the planarization layer in the display area.

16. The display device according to claim 12, wherein the pixel definition layer comprises a step structure on one side close to the non-display area, and the boundary of the light-emitting functional layer in the non-display area is between the step structure and the display area.

17. The display device according to claim 16, wherein the second conductive layer covers the step structure.

18. The display device according to claim 11, wherein the display panel further comprises:
a first bank, disposed on one side of the planarization layer away from the substrate, and at least a portion of the conductive trace is disposed between the first bank and the planarization layer; and
a second bank, disposed on one side of the planarization layer away from the substrate, and located on one side of the first bank away from the display area, wherein at least a portion of the conductive trace is disposed between the first bank and the planarization layer.

19. The display device according to claim 18, wherein the display panel further comprises:
an encapsulation layer, disposed on one side of the second conductive layer away from the substrate, wherein the encapsulation layer comprises a first inorganic encapsulation sub-layer, an organic encapsulation sub-layer, and a second inorganic encapsulation sub-layer sequentially stacked.

20. The display device according to claim 19, wherein the first inorganic encapsulation sub-layer is in direct contact with an upper surface of the conductive trace between the first bank and the second bank.
